(19) United States
(12) Patent Application Publication
(10) Pub. No.: US 2007/0076460 A1
(43) Pub. Date: Apr. 5, 2007

(54) Trapping bubbles of conducting matter in magnetic fields

(76) Inventor: Maurice H.P.M. van Putten, Cambridge, MA (US)

Correspondence Address: Maurice H.P.M. van Putten, 266 Pearl Street A, Cambridge, MA, 02139, US

(21) Appl. No.: 11/238,905

(22) Filed: Sep. 30, 2005

(51) Int. Cl. G11C 19/08

(52) U.S. Cl. 365/36

(57) ABSTRACT

Free suspension of matter comprising granular materials, liquids or plasmas, is of considerable interest in studying properties under controlled physical conditions. We describe a method for trapping bubbles of conductive matter in circularly polarized magnetic fields. In the preferred embodiments, the bubble assumes the topology of a torus or a hollow torus. We disclose the conditions for energy and pressure equilibrium for a fully ionized plasma. By suitable arrangement of current loops, the applied magnetic field can form a stable trap for exothermal plasmas.

### REFERENCES

1. Bollinger, J. J. & Wineland, D. J., 1990, Scientific American, TN-155
2. Boyd, T. J. M., & Sanderson, J. J., 2003, The Physics of Plasmas (Cambridge: Cambridge University Press)
3. Curtis, H., & Barnes, N. S., 1989, Biology (New York: Worth Publishers)
4. Dendy, R. (ed.), Plasma Physics: an introductory Course (Cambridge: Cambridge University Press)
5. Gilson, E. P., Davidson, R. C., Efthimon, P. C., Majeski, R., & Qin, H., 2003, Laser and Particle Beams, 21, 549
6. Gilson, E. P., Davidson, R. C., Efthimon, P. C., Majeski, R., & Qin, H., 2003, in Proc. 2003 Particle Accelerator Conference
7. Jackson, J. D., 1975, Classical Electrodynamics (New York: John Wiley & Sons)
8. Pahl, A., Eikema, K. S. E., Walz, J. & Hainsch, T. W., 2000, Hyperfine Interactions, 127, 181
9. Paul, W., 1989, Nobel Lecture
10. Ribicki, G. B., & Lightman, A. P., 1979, Radiative Processes in Astrophysics (New York: John Wiley & Sons)
11. van Putten, M. H. P. M., & Felce, A. G., 1996, A method and device for uniform heating, U.S. Pat. No. 5,533,567
12. van Putten, M. H. P. M., van Putten, M. J. A. M., van Putten, A. F. P., & van Putten, P. F. A. M., 1995, U.S. Pat. No. 5,426,969
13. van Putten, M. H. P. M., van Putten, M. J. A. M., van Putten, A. F. P., & van Putten, P. F. A. M., 2002, EU Patent 94202293.0
14. van Putten, M. H. P. M., 1999, Science, 184, 15
15. van Putten, M. H. P. M., & Ostriker, E. C., 2001, ApJ, 552, L31
16. van Putten, M. H. P. M., & Levinson, A., 2003, ApJ, 584, 937
17. van Putten, M. H. P. M., 2005, Gravitational raddiation, luminous black holes and gamma-ray bursts (Cambridge: Cambridge University Press)
18. Wineland, D. J., Bollinger, J. J., Itano, W. M., & Prestage, J. D., 1985, J. Optical Soc. America B., 2, 1721

### BACKGROUND OF THE INVENTION

Free suspension of Type II superconducting solids in an external magnetic dipole field is perhaps the best known example of a magnetic trap. It operates by magnetic buoyancy in response to the Meisner effect, whereby the surface is a perfect mirror for an effective magnetic moment interaction with surrounding magnetic fields.

Trapping particles in free suspension is key to the study of collective properties under extreme conditions. It also serves as a method for storage in high-energy physics experiments. Dedicated trapping mechanisms have been developed for the study of exotic states of matter at ultra-low temperatures. Individual ions have been successfully trapped by the focusing effect of time-harmonic quadrupole electric fields. This technique applies to trapping ions at small numbers (Wineland et al. 1985; Paul 1989; Bollinger & Wineland 1990; Pahl et al. 2000; Gilson et al. 2003a,b; Pahl et al. 2000). Some of these ideas have been combined with laser-induced radiation pressures. Neutral particles can be trapped by interacting with their magnetic moment, forming stable ensembles about the hyperbolic point of multipole magnetic fields (“magnetic bottles”). In the adiabatic approximation of collisionless ultracold neutrinos, the particle trajectories track the equipotential surfaces of constant magnetic field-strength. The latter form a center at the corresponding hyperbolic point of the magnetic field. This structure has been realized in spherical and toroidal magnetic bottles.

These existing trapping mechanisms operate in the limit of strong magnetic fields and ultra-low temperatures. In this limit, the particle trajectories are determined by the magnetic field alone with negligible perturbation thereof by the backreaction of the trapped particles. This mode of operation has some limitations. In practice, most fluids or plasmas appear at finite temperatures and pressures which are charge-neutral, not superconducting, and with largely randomized intrinsic magnetic moments. Their macroscopic pressures often render continuous confinement by radiation pressure impractical.

We here focus on the free suspension of matter with finite electrical conductivity, and pose the problem of (1) trapping bubbles of largely unmagnetized matter at finite pressures and (2) suppressing collisional drift across field-lines (“leakage”).

Matter at finite pressures can form as bubbles in a magnetic field, whose surfaces form a contact discontinuity with isobaric streamlines of the magnetic field. According to the magnetohydrostatic jump conditions, the strength of the magnetic field is constant along the surface of the bubble. This isobaric surface condition does not arise in existing magnetic bottles, wherein curves of constant magnetic field-strength are generally oblique to the streamlines of the magnetic field. This distinction can be associated with the induced surface currents on the bubble, which are homologous to surface currents on Type II superconductors. This backreaction has no counter part in the dilute limit of small particle ensembles in magnetic bottles. The condition of constant magnetic field-strength along streamlines on the surface of the bubble poses a free-surface problem, which closely resembles that of air bubbles trapped in water. For example, a bubble at a hyperbolic point of the magnetic field is similar to an air bubble in the corner of water-pipe, upon neglecting surface tension effects in the latter.

Collisional drift and magnetic diffusion represent the presence of finite electrical conductivity. In a perfect trap, collisional drift is countered by an ingoing Poynting flux associated with inductive heating. Doing so in a magnetic reconnection layer produces magnetic confinement of all charged particles. This introduces a relation between inductive heating and magnetic pressure support on the surface of a trapped bubble. In particular, the surface of a bubble is subject to uniform heating upon exposure to circularly polarized magnetic fields: time-varying magnetic fields which rotate while preserving a constant magnitude.

It has been appreciated that magnetic fields of constant field-strength are topologically not allowed on surfaces homeomorphic to a sphere. Indeed, bubbles which are homotopic to a sphere that are exposed to an approximately constant magnetic field-strength develop characteristic cusps, as in the open topology of magnetic mirrors. The cusp hereby forms a singularity which effectively circumvents the topological constraint on smooth surfaces. Steady-state cusps are notorious as a channel for leakage. For this reason, the topology of a torus has generally been considered more favorable than that of a sphere in the design of devices for magnetic traps.

It will be appreciated that bubbles of unmagnetized matter trapped in a magnetic field are different from the magnetic confininement of high-temperature plasmas in a Tokamak. In a Tokamak device, the plasma is completely permeated with magnetic fields wherein the hydrostatic-to-magnetic pressure, β, is less than 1. In contrast, a bubble trapped in a magnetic field assumes β≡1, representing balance of hydrostatic pressure inside the bubble relative to magnetic pressure outside the bubble. Furthermore, a bubble trap is distinct from the so-called Θ-pinch configuration in that the latter seeks short-duration bursts of high-pressure confinement, whereas the former seeks long-duration continuous operation.

Here, we disclose a method for trapping bubbles of conductive matter in magnetic fields. Our implementation is based on modulating orientations following the alternating direction method for drift elimination in vector sensors and a method for uniform heating (van Putten et al. 1995; van Putten & Felce 1996). The magnetic field hereby entrains but does not permeate the trapped matter by acting as a magnetic wall around the bubble (van Putten 1999; van Putten & Ostriker 2001; van Putten & Levinson 2003; van Putten 2005). As a result, magnetohydrodynamical turbulence, if any, is confined to a boundary layer in the bubble. The magnetic Reynolds number is bounded by the Dreicer value of the induced electric fields. We shall disclose
1. A method for trapping conductive matter as largely unmagnetized bubbles, such as granular materials, fluids and plasmas, by circularly polarized magnetic fields;
2. The stability of plasma bubbles in energy and pressure balance, between bremsstrahlung and hydrostatic pressure in the bubble and input from the applied magnetic field;
3. Applications to exothermal plasmas, such as due to nuclear reactions.

### SUMMARY OF THE DISCLOSURE

We here describe a method for trapping bubbles of largely unmagnetized matter with finite electrical conductivity circularly polarized magnetic fields. The surface of the bubble forms a contact discontinuity with isobaric magnetic streamlines, and develops a dissipative boundary layer involving collisional drift accross magnetic field-lines and inductive heating.

The isobaric streamlines of the magnetic field require closure by periodic boundary conditions along either one of two generally orthogonal directions along the surface of the bubble. The congruence of magnetic streamlines hereby forms a torus (with finite helicity) in either of these two orthogonal directions. A circularly polarized magnetic field thus closes in alternatingly orthogonal directions. The realization will be given in our preferred embodiments.

Collisional drift across magnetic flux-surfaces is an inevitable consequence of fluids with finite electrical conductivity. It is a manifestation of magnetic diffusion and dissipation of thermal energy in the fluid. It can be countered by inductive heating through the associated ingoing Poynting flux and ingoing E×B-drift. Sufficient heating hereby creates a perfect trap of charged particles. This can be achieved by adjustment of the frequency of the applied magnetic field.

The equilibrium equations for a trap are given by energy and pressure balance, of radiation and hydrostatic pressure in the trapped matter and input received from the applied magnetic field. As disclosed herein, these two balance conditions are governed by, respectively,

$${σ}_{B}^{2} = < {B}^{2} > , {σ}_{B}^{2} \sqrt{\frac{Ω}{σ}} , \qquad ( 1 )$$

where B denotes the magnetic field with dispersion σ_{B} and angular frequency Ω=2πf, and σ the electric conductivity of the fluid. Table I provides a brief overview of characteristic physical parameters for a fully ionized, high-temperature plasma.

Table I. Physical parameters of bubbles trapped in magnetic fields. The bubble has dimension R=R₁ cm and the magnetic field has strength B=B_{1T}T and frequency f=10 f₁Hz. The plasma in the fluid has a characteristic ion density nᵢ=10¹⁴ n₁₄cm⁻³ with ion charge eZᵢ, electron density nₑ=nᵢZᵢ, and temperature T=10⁴ T₄eV, assuming isothermal populations of ions and electrons (Tₑ=Tᵢ) and a Coulomb logarithm ln Λ≃17. Here k_{B}=1.38×10⁻²³ J/K denotes the Boltzman constant, mₑ and mᵢ=Aᵢmₚ denote the electron and ion mass, ε₀ and μ₀ the electric permittivity and magnetic permeability of vacuum and e the elementary charge. (Adapted from Ribicki & Lightman (1979); Dendy (1996); Boyd & Sanderson (2003).)

| QUANTITY | SYMBOLIC EXPRESSION | DIMENSIONAL EXPRESSION |
|---|---|---|
| Hydrostatic pressure | p = (nᵢ + nₑ)k_{B}T/Z | 1.6 n₁₄(1 + Zᵢ)T₄ bar |
| Ion sound speed | ${c}_{s} = \sqrt{\frac{{T}_{e}}{{m}_{i}}}$ | 8.3 × 10⁷T₄^{1/2}Aᵢ^{-1/2} cm s⁻¹ |
| Debye length | ${λ}_{D} = \sqrt{\frac{{ε}_{0} {T}_{e} ( 1 + {Z}_{i} )}{{n}_{i} {Z}_{i}^{2} {e}^{2}}}$ | $7.5 \times {10}^{- 3} {T}_{4}^{1 \text{/} 2} {{n}_{14}^{- 1 \text{/} 2} ( \frac{1 + {Z}_{i}}{{Z}_{i}^{2}} )}^{1 \text{/} 2} cm$ |
| Plasma parameter | nₑλ_{D}³ | O(10⁷) |
| Plasma frequency | ${ω}_{p} = \sqrt{\frac{{n}_{e} {e}^{2}}{{ε}_{0} {m}_{e}}}$ | 5.6 × 10¹¹ n₁₄^{1/2}Zᵢ^{1/2} s⁻¹ |
| Ion collision frequency | ${υ}_{i} = {( \frac{{m}_{e}}{{m}_{i}} )}^{1 \text{/} 2} \frac{{Z}_{i}^{2}}{\sqrt{2}} {v}_{e}$ | 82 n₁₄Zᵢ⁴T₄^{-3/2} s⁻¹ |
| Electron collision frequency | ${υ}_{e} = \frac{4 \sqrt{2 π} {n}_{i} {Z}_{i}^{2} {e}^{4} ln Λ}{{( 4 {πε}_{0} )}^{2} 3 {m}_{e}^{1 \text{/} 2} {T}_{e}^{3 \text{/} 2}}$ | 5 × 10³ n₁₄Zᵢ²T₄^{-3/2} s⁻¹ |
| Magnetic pressure | ${p}_{B} = \frac{1}{2 {μ}_{0}} {B}^{2}$ | 4B_{1T}² bar |
| Alfvén speed | ${c}_{A} = \frac{B}{\sqrt{{μ}_{0} {n}_{i} {m}_{i}}}$ | 2.2 × 10⁸ B_{1T}n₁₄^{-1/2} Aᵢ^{-1/2} cm s⁻¹ |
| Ion gyro frequency | ${ω}_{ci} = \frac{eB}{{m}_{i}}$ | 9.6 × 10⁷ B_{1T}Aᵢ⁻¹ s⁻¹ |
| Electron gyro frequency | ${ω}_{ce} = \frac{eB}{{m}_{e}}$ | 1.8 × 10¹¹ B_{1T} s⁻¹ |
| Ion Larmor radius | ${r}_{Li} = \frac{{c}_{s}}{{ω}_{ci}}$ | 0.86T₄^{1/2} Aᵢ^{1/2} B_{1T}⁻¹ cm |
| Electron Larmor radius | ${r}_{Le} = \sqrt{\frac{{m}_{e}}{{m}_{i}}} {r}_{Li}$ | 37T₄^{1/2} B_{1T}⁻¹ cm |
| Ion diffusion constant | ${D}_{i ⊥} = {r}_{Li}^{2} {υ}_{i}$ | 3.0 × 10⁻⁵ B_{1T}⁻²n₁₄AᵢZᵢ⁴T₄^{-1/2} cm² s⁻¹ |
| Electron diffusion constant | ${D}_{e ⊥} = {r}_{Le}^{2} {υ}_{e}$ | 9.8 × 10⁻⁷ B_{1T}⁻²n₁₄Zᵢ²T₄^{-1/2} cm² s⁻¹ |
| Conductivity | $σ = \frac{{n}_{e} {e}^{2}}{{α}_{e} {m}_{e} {υ}_{e}}$ | 6.0 × 10⁸ Zᵢ⁻¹αₑ⁻¹T₄^{3/2} (Ω m)⁻¹ |
| Spitzer correction | ${α}_{e} = \frac{1 + 1.198 {Z}_{i} + 0.222 {Z}_{i}^{2}}{1 + 2.966 {Z}_{i} + 0.753 {Z}_{i}^{2}}$ | 0.5129 − 0.2945 |
| Magnetic diffusivity | ${D}_{B} = \frac{1}{{μ}_{0} σ}$ | 14αₑZᵢT₄^{-3/2} cm² s⁻¹ |
| Resistive skin-depth | $δ = \sqrt{\frac{2 {D}_{B}}{Ω}}$ | 0.65ƒ₁^{-1/2} Zᵢαₑ^{1/2}T₄^{-3/4} cm |
| β-parameter | $β = \frac{2 {μ}_{0} p}{{B}^{2}}$ | 1 |
| Gradient drift velocity | ${v}_{d} = \frac{{βD}_{B}}{2 δ}$ | 1 × 10³ƒ₁^{1/2} αₑ^{1/2}T₄^{-3/4} cm s⁻¹ |
| Poynting drift velocity | $w = \frac{1}{2} ΩR$ | 31ƒ₁R₁ cm s⁻¹ |

We organize this disclosure by discussing (I) the shape of a bubble, (II) the topology of bubbles trapped in circularly polarized magnetic field and the (III) stability of trapped plasma bubbles, followed by an application to (IV) bubbles of exothermal plasmas.

### I. The Shape of a Bubble

A bubble in a magnetic field is a cavity, filled with a conductive, pressurized and largely unmagnetized fluid. To calculate the shape of a bubble, we consider a two-dimensional bubble trapped in an ideal magnetic mirror. The free surface of the bubble represents a congruence of isobaric magnetic streamlines, which can be solved by a hodograph transformation. The characteristic cusps appearing in a bubble trapped in a magnetic mirror are similar to the cusps of an air bubble trapped in a corner of a water-pipe. The latter is described by a normalized complex velocity potential Ω(z),

$$z = {\int }_{0}^{Ω} \frac{ⅆ Ω}{{( Ω + \sqrt{{Ω}^{2} - 1} )}^{1 / 2}} . \qquad ( 2 )$$

satisfying the local asymptotics Ω(z)˜z² and Ω′(z)˜z for large z of a corner flow. The bubble boundary is hereby of the form
x^{2/3}+y^{2/3}=a^{2/3} (3)
where a is a constant. Similarly, a bubble in an idealized magnetic mirror formed by two point-like magnetic dipole moments is subject to the asymptotic condition of a divergent magnetic field-strength. This gives a bubble with two cusps, whose complex velocity Ω′(z) has the topology of a Bowman's capsule (Curtis & Barnes 1989). This gives rise to

$$z = {\int }_{0}^{Ω} \frac{ⅆ Ω}{{( {Ω}^{2} - 1 + Ω \sqrt{{Ω}^{2} - 2} )}^{1 / p}} \qquad ( 4 )$$

with p>2, using a branch cut connecting ±\sqrt{2} such that Ω\sqrt{Ω²−2} is positive on Q²>2. A special case is p=2. In this event, the problem reduces to the air-bubble trapped in a water pipe, described piece-wise by (3) as shown in FIG. 1. This can be made explicit by putting Ω²−1=cos(2φ). For p>2, the bubble is more flat than that shown in FIG. 1, in that its tangent never becomes parallel to the y-axis. The two terminal cusps of the bubble point towards the two magnetic dipole moments which together form a magnetic mirror.

It will be appreciated that in general the precise shape of the bubble depends on the details of the current rings in the magnetic mirror configuration.

In bubbles of matter with finite conductivity, the matter is unmagnetized except for a magnetic boundary layer forming a contact discontinity with the surrounding magnetic field. Deviations from the isobaric condition may arise, if the fluid develops internal vorticity, whose stagnation pressures can modulate the surrounding magnetic pressures. Such vorticity is known to arise, for example, in air-bubbles rising in still water or in an air bubble trapped in the corner of a water-pipe. However, vorticity-induced non-uniform pressures are less likely to be important in bubbles in magnetic fields. (The vorticity induced by the gradient drift-velocity v_{d}, see Table I, is everywhere tangential to the boundary of the bubble, and hence does not produce stagnation points.) In this approximation, the bubble shape poses a free boundary problem close to the potential flow (4) with suitable generalization to three dimensions.

### II. Bubbles in Circularly Polarized Magnetic Fields

Effective trapping of a bubble of a non-ideal unmagnetized matter requires maintaining a circular polarization of the magnetic field in view of the isobaric streamline condition on the surface of the bubble. To this end, we employ alternating poloidal and toroidal states of the magnetic field, which represent mutually orthogonal congruences of magnetic streamlines. It is customary to refer to these congruences as having an open topology, as in a magnetic mirror, or a closed topology, as in a torus. Here, reference is made to the topology of the magnetic field-lines restricted to the region enclosed by the surrounding electric current loops. This is distinct from the global topology of the magnetic field-lines, which is always closed.

The surface of a torus allows a tangent magnetic field which is everywhere constant in magnitude. The surface of a torus can be covered by a congruence of magnetic field-lines, whose helicity (equivalent to the winding number in toroidal topology) ranges from −∞ to ∞. Time-variations in the helicity hereby correspond to a circularly polarized magnetic field on the surface of the torus, such that the average magnetic field is everywhere zero while its magnitude can be kept constant.

We wish to trap matter largely unmagnetized with vanishing internal currents and generally nonzero surface currents, in an effort to circumvent some of the well-known magneto-hydrodynamical instabilities in magnetically permeated plasmas. This prohibits the state of a constant nonzero helicity along the surface of a torus. We consider a multipole magnetic field as seen in poloidal cross-section, e.g., a dipole, as in magnetic mirrors, quadrupole or sectupole, as in a magnetic bottle. The instantaneous shape of the bubble thus confined develops cusps, here in the form of rings around the axis of symmetry of the torus. While this provides a channel for leaks in steady-state, cusps which form subsequently with opposing orientations of the magnetic field will be effectively closed by the action of incoming Poynting flux associated with inductive heating in the surface.

The magnetic field becomes circularly polarized, by alternating between multipole poloidal and toroidal congruences of magnetic streamlines. This introduces a perfect trap for charged particles. In this process, a trapped bubble continuously changes shape, respectively, between cuspy in the state of poloidal streamlines and smooth in the state of toroidal streamlines. FIG. 2 shows the alternation between a toroidal and a poloidal states of the congruences of magnetic field-lines in the form of a sequences of four windows for, respectively, for the dipole case (top row) and quadrupole case (bottom row). The axis labels refer to the Cartesian x-axis and z-axis of the plane of a poloidal cross-section of the bubble, where R denotes the major radius of the torus in the toroidal state of the magnetic field. Windows (A) and (C) show the two toroidal states of the magnetic field. Note the switch in direction of the magnetic field in (A) and (B). Windows (B) and (D) show the poloidal state of the magnetic field, where the arrows indicate the direction of the magnetic field along the shown congruences of the magnetic streamlines. Note the switch in direction of the magnetic field in (B) and (D).

In the method of introducing circular magnetic polarization by alternating states of the magnetic streamlines above, it is important to stay away from a resonant interaction of the quadrupole oscillations in the magnetic force-field with the ion-accoustic modes of the fluid.

### III. Stability of Trapped Plasma Bubbles

A largely unmagnetized trapped bubble satisfies β≃1. In a fully ionized state, the bubble produces bremsstrahlung, which is optically thin except for self-absorption below the plasma frequency and an exponential cut-off defined by the temperature of the plasma. The thermodynamic equilibrium state of a bubble is therefore defined by balance of pressure and energy flux, given by

$$\begin{matrix}{E}_{1} \text{:} {n}_{14} = \frac{25}{1 + {Z}_{i}} {B}_{1 T}^{2} {T}_{4}^{- 1} & ( 5 ) \\ {E}_{2} \text{:} {P}_{d} = {P}_{B} , & ( 6 )\end{matrix}$$

where P_{d} denotes the power input in inductive heating and P_{B} the power output in bremsstrahlung. The energy balance (6) assumes a perfect trap, wherein conductive heat losses by spurious diffusion between the bubble and the surrounding walls can be neglected. It also neglects electron synchrotron emission in the boundary layer of the bubble. The latter approximation is valid, provided that the boundary layer is thin. For a bubble with toroidal shape of major radius R and minor radius b,

$${P}_{B} = 0.34 {n}_{14}^{2} {T}_{4}^{1 / 2} {Z}_{i}^{3} {b}^{2} {R}_{1} W = \frac{212 {Z}_{i}^{3}}{{( 1 + {Z}_{i} )}^{2}} {B}_{1 T}^{4} {T}_{4}^{- 3 / 2} {b}_{1}^{2} {R}_{1} W , \qquad ( 7 )$$

ignoring corrections of order unity by the Gaunt factor.

Exposed to a time-harmonic magnetic field with angular frequency Ω, the bubble develops a magnetic reconnection layer with skin-depth δ (Table I). The tickness δ of the magnetic boundary layer is governed by the magnetic Reynolds number which, for a fluid with characteristic radius R, can be defined as

$${R}_{M} = \frac{Ω {R}^{2}}{{D}_{B}} = 4.5 \frac{{T}_{4}^{3 / 2} {f}_{1} {R}_{1}^{2}}{{Z}_{i} α} . \qquad ( 8 )$$

This gives rise to a resistive skin-depth δ which we insist is small relative to the scale-height h of the bubble,

$$\frac{δ}{h} = 0.65 \frac{{Z}_{i} {α}_{e}^{1 / 2}}{{f}_{1}^{1 / 2} {T}_{4}^{3 / 4} {h}_{1}} << 1 , \qquad ( 9 )$$

where h=h₁cm. This condition is satisfied even at moderate magnetic Reynolds numbers (8). The magnetic field is hereby effectively excluded from the region inside of the bubble. This ensures that the shape of the bubble is described as given previously.

Energy is dissipated in the magnetic reconnection layer due to inductive heating by the circularly polarized tangential magnetic field. This can be calculated by integration of the power-density over the skin-depth (adapted from Jackson (1975))

$${P}_{d} = 2 {π}^{2} {Ωμ}_{0}^{- 1} {B}^{2} {b}^{2} R ( \frac{δ}{b} ) ≃ {10}^{3} {f}_{1} {B}_{1 T}^{2} {b}_{1}^{2} {R}_{1} ( \frac{δ}{b} ) W . \qquad ( 10 )$$

When the frequency of the oscillations of the magnetic field is not too large, the induced electric field remains below the Dreicer value. By the Einstein relations D/μ=T/q between the diffusion constant D and the mobility μ=q(mν)⁻¹ in terms of the particle mass m and charge q subject to a collision frequency ν at a temperature T, the ratio of ion-to-electron current satisfies

$$\frac{{Z}_{i} {μ}_{i} {n}_{i}}{{μ}_{e} {n}_{e}} = \frac{{Z}_{i} {m}_{e} {ν}_{e}}{{m}_{i} {ν}_{i}} = \sqrt{\frac{{m}_{e}}{{m}_{i}}} \frac{{Z}_{i}^{2}}{\sqrt{2}} << 1 , \qquad ( 11 )$$

showing the familiar result that, for light elements, most current is carried by the electrons (Dendy 1996). Therefore, we compare the associated electron drift velocities, v_{J}≃J/nₑe, μ₀J≃B/δ, with their thermal velocities v_{eT} (Dendy 1996). Using (5), this gives rise to the condition

$$\begin{matrix}\frac{{υ}_{J}}{{υ}_{eT}} ≃ \frac{B}{{μ}_{0} {δn}_{e} e} \sqrt{\frac{{m}_{e}}{{T}_{e}}} = 0.21 \frac{{f}_{1}^{1 / 2} {B}_{1 T} {T}_{4}^{1 / 4}}{{α}_{e}^{1 / 2} {Z}_{i}^{2} {n}_{14}} << 1 , \\ or & ( 12 ) \\ {B}_{1 T} {b}_{1} >> \frac{1 + {Z}_{i}}{120} {( \frac{δ}{b} )}^{- 1} . & ( 13 )\end{matrix}$$

Outside this range, runaway electrons can be expected and the conductivity σ will deviate from the standard estimate given in Table I. Rewriting (6), we have

$${B}_{1 T} {b}_{1} ≃ 0.24 \frac{1 + {Z}_{i}}{\sqrt{{Z}_{i} {α}_{e}}} {( \frac{δ}{b} )}^{- 1 / 2} . \qquad ( 14 )$$

It follows that bubbles in equilibrium (9) and (13) exist in the parameter range

$$1.2 \times {10}^{- 3} {α}_{e} {Z}_{i} ⪡ \frac{δ}{b} ⪡ 1. \qquad ( 15 )$$

Thus, (15) represents a bubble constraint imposed by the microphysics of the plasma.

The stability of the equilibrium state (5-6) can be investigated by considering small perturbations about this equilibrium. We have δ(P_{d}−P_{B})/P_{d}=−2δB/B+(3/4)δT/T about (6). By conservation of particle number, δT/T=2δb/b+δR/R+2δB/B, stability follows whenever δB/B=3δb/b+(3/2)δR/R. That is, a device for creating a magnetic bubble trap must be such to create a radially non-uniform magnetic field-strength by an arrangement of current loops satisfying

$$B ( r ) = {{B}_{0} ( \frac{r}{{r}_{0}} )}^{3 / 2 + {p}_{2}} {( \frac{ρ}{{b}_{0}} )}^{3 + {p}_{1}} ( {p}_{1} , {p}_{2} > 0 ) , \qquad ( 16 )$$

where we coordinatize the torus in (r, φ, z) with cylindrical radius r, height z such that z=ρ sin θ, r=([R+ρ cos θ]²+z²)^{1/2}.

### IV. Bubbles of Exothermal Plasmas

As an application, we consider a bringing a trapped ionized plasma bubble to a thermonuclear fusion temperature of above 10 keV.

Thermonuclear fusion experiments usually involve two-body interactions of light elements, e.g., deuterium and tritium with nuclear reaction energies W_{N}=3.5 MeV in newly created alpha particles and about 14 MeV in fast neutrons. Most of W_{N} (some 95% Dendy (1996)) is absorbed by the plasma in the form of heat. This changes the energy balance from E₂ in (6) with an additional heat source P_{f} due to fusion reactions, into
E₂′: P_{f}+P_{d}=P_{B} (17)
for a perfect trap without conductive heat losses to the surrounding walls. For a trapped bubble in the equilibrium state (5-6) of toroidal shape with volume 2π²bR², we have

$${P}_{f} ≃ 39 κ {n}_{14}^{2} {T}_{4}^{1 / 2} {b}_{1}^{2} {R}_{1} W = \frac{24 κ}{{( 1 + {Z}_{i} )}^{2}} {B}_{1 T}^{4} {T}_{4}^{- 3 / 2} {b}_{1}^{2} {R}_{1} kW . \qquad ( 18 )$$

Here, κ=κ(T)≦1 is a normalized thermal suppression factor containing the microphysics of fusion reactions. We scale about T=1.16×10⁸K, near the maximal value <σv>≃10⁻²¹ m³ s⁻¹ at T*≃8×10⁸K where κ(T*)=1. At very low temperatures, κ(T) decreases exponentially to zero, whereas at very high temperatures, κ(T) decreases algebraically to zero (see, e.g., (Dendy 1996)). Since P_{B}>0, it will be appreciated that the new condition (17) implies a working temperature considerably away from the maximum, where P_{f}<P_{B} corresponding to 115κ(T)<1.

In deuterium-tritium reactions, we have an energy output Pₙ=4P_{f} in fast neutrons of 14 MeV/3.5 MeV times P_{f}. These particles leave the plasma without any Coulomb frictional losses, and are of interest to the extraction of useful energy from the bubble. A net energy output Pₙ>P_{d} while P_{f}<P_{B} arises when P_{d}/4<P_{f}<P_{B}, or

$$\frac{4}{5} {P}_{B} < {P}_{f} < {P}_{B} . \qquad ( 19 )$$

subject to (5), (17), and the bubble constraint (15). The window (19) corresponds to an implicit temperature window

$$\frac{4}{5} < \frac{κ ( T )}{115} < 1. \qquad ( 20 )$$

The above shows the existence of a window (20) for thermonuclear reactions in a stable trapped state of the bubble. Note that this controlled thermonuclear reaction rate is less than about 1% of the maximal possible fusion rate at the given density. This limit is generally enhanced by any additional synchrotron emission from the boundary layer in the bubble. It may be compared with the likewise moderate reaction rates in controlled fission reactors. Starting at T<T*, it will be appreciated that in going beyond (20), the bubble becomes thermally unstable which triggers a sudden transition to a much higher temperature T>T* such that again (20) is satisfied. This shows that, in principle, stable fusion reactions are possible in a bubble at two different temperatures, either below T* or above T*.

### SURVEY OF THE DRAWINGS

The shape of a trapped bubble is generally as shown in FIG. 1. The shape is determined by the condition that the boundary of the bubble forms an isobaric streamline of the surrounding magnetic field. In the limit of high electrical conductivity, the magnetic diffusion boundary layer in the bubble is thin relative to the linear size of the bubble even at low oscillation frequencies of the magnetic field. In this case, the problem of determining the shape of the bubble is analogous to that of an air-bubble trapped in a water-pipe in the approximation of a potential flow. Shown is the illustrative case of a bubble trapped in a magnetic mirror, consisting of two magnetic dipole moments at either side of the two cusps following a hodograph transformation in two dimensions.

FIG. 2 shows the dynamical evolution of a cicularly polarized magnetic field surrounding the bubble. In this approach, a constant magnetic field-strength preserves continuous pressurization of the bubble, while the rotation of magnetic field causes exponential decay into the bubble according to the magnetic diffusion equation. This decay is rapid even at moderate magnetic Reynolds numbers, whereby the fluid inside the bubble remains largely unmagnetized. Rotation is realized through an alternating sequence of toroidal and poloidal states of the magnetic field, as shown in the four windows in each row, each corresponding to one-quarter of a period of the rotating magnetic field. The top row shows the case of a poloidal state given by a dipole magnetic mirror, while the bottom row shows the case of a poloidal state given by a quadrupole magnetic mirror. All windows refer to a poloidal cross-section in the xz-plane of the congruences of the magnetic streamline in either of the two states of the magnetic field. Here, R denotes the major radius of the toroidal magnetic field in the toroidal states (A) and (C) with either sign of of the magnetic field. Windows (B) and (D) show the intermediate poloidal state of the magnetic field, likewise shown with either sign as indicated by the arrows.

FIG. 3 shows an open view of the first preferred embodiment, wherein the fluid forms a torus in both the toroidal and poloidal state of the magnetic field. The poloidal state is created by dipole magnetic mirrors (A) or quadrupole magnetic mirrors (B). The latter correspond to the two rows shown in FIG. 2. The toroidal state of the magnetic field is created by the poloidal current rings (T), while the poloidal state of the magnetic field is created by the toroidal current rings (P). The two different choices in the orientation of the currents in (P) refer to the dipole, respectively quadrupole magnetic mirrors.

FIG. 4 shows an extension of FIG. 3A, by stacking a series of the units shown in FIG. 3A in a circle, thus forming a large torus. As indicated by the open views shown, the stacking is such that the magnetic dipole mirrors are adjacent to one another with commensurate orientation of the magnetic field. Thus, the poloidal state of the magnetic field and the trapped bubble in each of the units of FIG. 3A now create a large, hollow torus. For this reason, we shall refer to this state as the (large) toroidal state of the magnetic field. In contrast, the toroidal state of the magnetic field in each of the units of FIG. 3A now represent a partition of the large hollow torus into segments, representing a plurality of small tori. We shall refer to this state as the segmented torus state in the poloidal state of the magnetic field. Note the switch in the “toroidal” and “poloidal” in discussing the state of the magnetic field of a single unit of FIG. 3A to that of a large torus consisting of a stacked series of the same units.

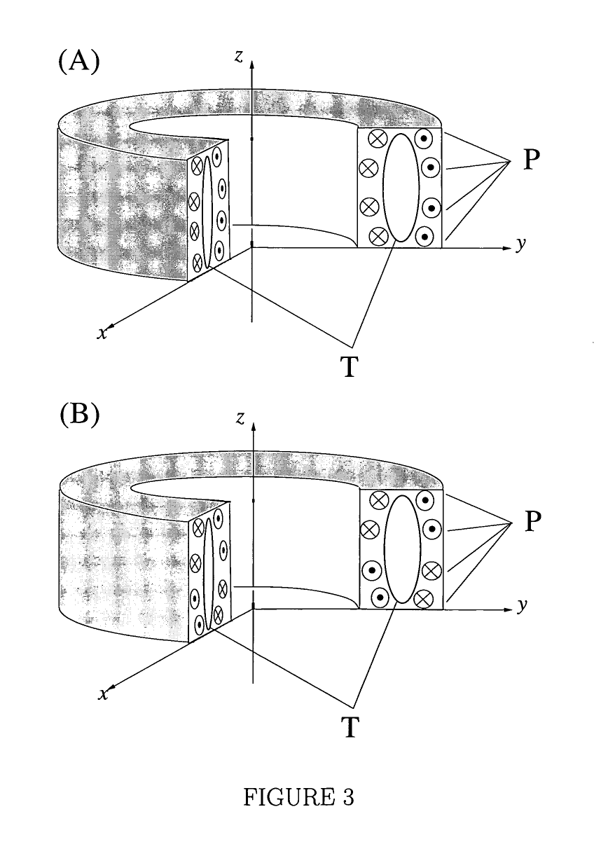

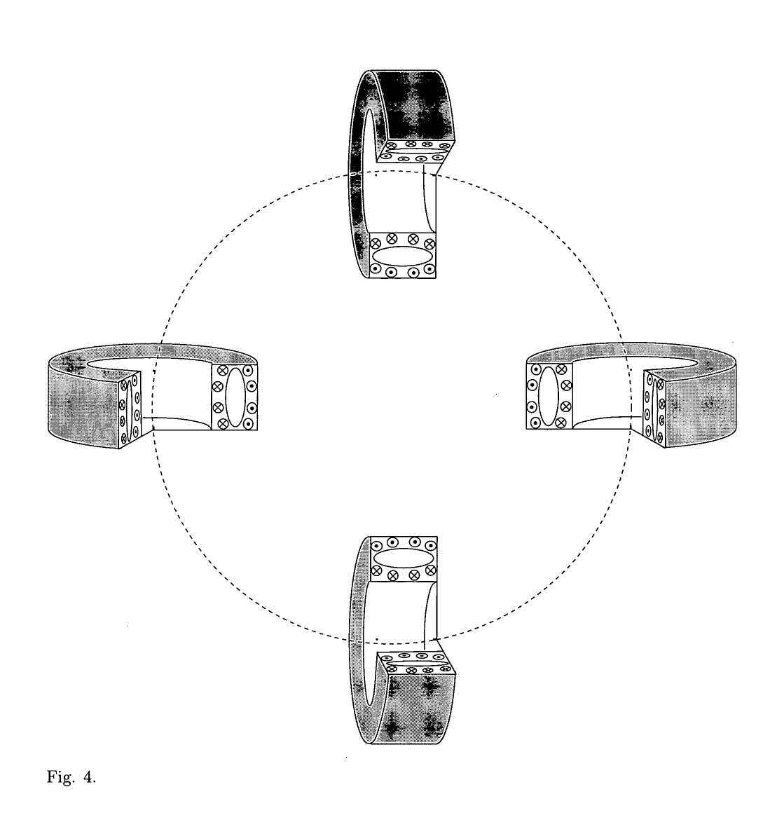

In what follows, we shall refer to the embodiment depicted in FIG. 3 as a simple torus configuration, and to that depicted in FIG. 4 as a segmented torus configuration.

### PREFERRED EMBODIMENTS

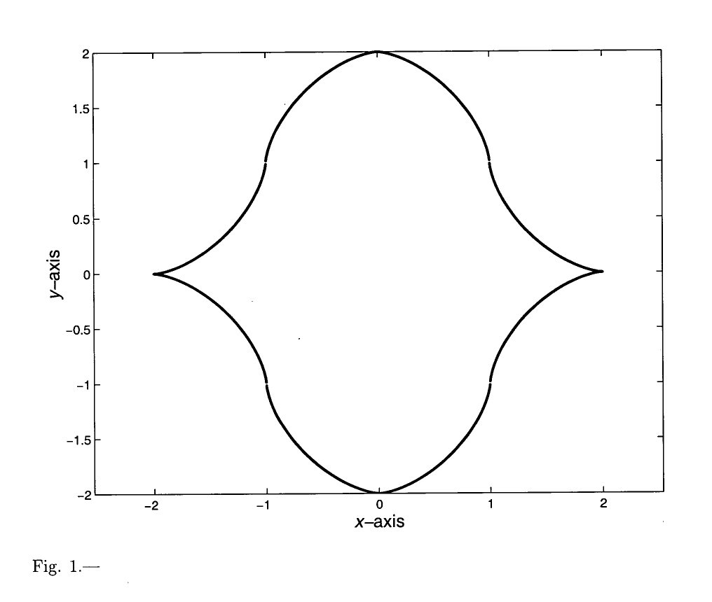

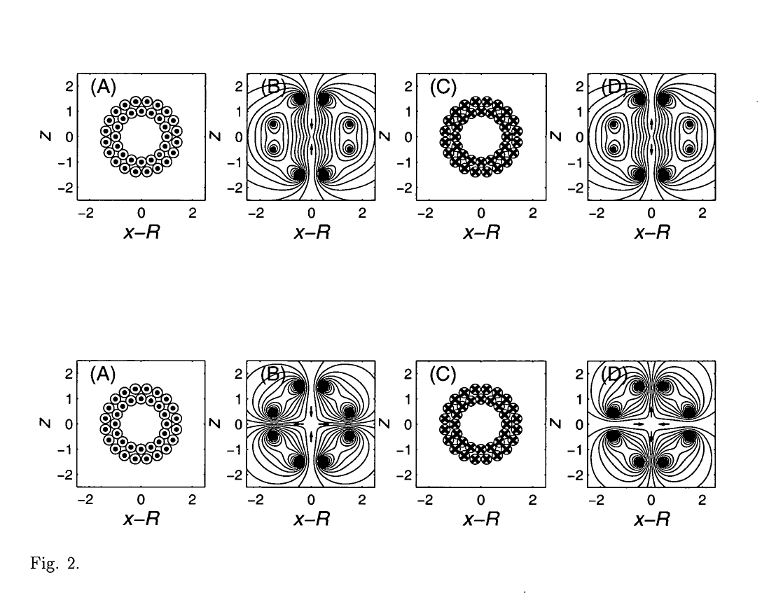

The First preferred embodiment consists of the simple torus configuration shown in FIG. 3. Here, a combination of two pluralities of electric current loops is installed, where one plurality is used to create closed toroidal magnetic field lines (T), and the other plurality is used to created a multipole poloidal magnetic field (P). FIG. 3 shows the case for a dipole (top) and a quadrupole poloidal magnetic field (bottom). These two pluralities are excited by a time-harmonic current source, such as to create the sequences of four states of the magnetic field as shown in FIG. 2, by taking their excitation to be out-of-phase by one-quarter of a period. The Second preferred embodiment consists of a segmented torus configuration shown in FIG. 4. Here, the dipole configuration as shown in FIG. 3 (top) is stacked toroidally, such that the open magnetic field-lines in poloidal mode form closed toroidal loops. The result is a hollow torus in the intermediate toroidal state, corresponding to (T) in FIG. 3, and a segmented torus in the intermediate poloidal state, corresponding to (P) in FIG. 3. This configuration has the unique property that in both these intermediate states, the magnetic field-lines form toroidal loops. This configuration, therefore, has formally no leaks, even if the trap in the intermediate poloidal state is not ideal.

In both the First and Second preferred embodiment, the current loops can be constructed using modern superconducting materials, in order to efficiently reach the desired magnetic field-strengths on the order of a few Tesla. The complete system further comprises a fluid or plasma injector. In the application to exothermal plasmas, the embodiment also contains a collector of fast neutral particles such as neutrons produced in nuclear reactions. Thermal energy can thus be mediated to a generator in a fashion very similar to that in existing nuclear reactors and Tokamak designs.

It will be appreciated that in a final design arguments favoring one technology over another are ultimately determined by a combination of aspects such as cost, magnets, fuel injectors and shielding materials. While alternate implementations are conceivable, we have presented the First and Second possible implementations to illustrate real-world realizations, which should not be construed as limiting the method contained herein.

We claim:

1. A method for trapping bubbles of conductive matter in a circularly polarized magnetic field, with the property that said magnetic field alternates between toroidal and poloidal states corresponding to two mutually orthogonal congruences of magnetic streamlines, said states being powered by two orthogonal pluralities of electric current loops.

2. A method for trapping bubbles of conductive matter according to claim 1, with the property that said matter is pressurized and largely unmagnetized by control of the strength and oscillation frequency the magnetic field.

3. A method for trapping bubbles of conductive matter according to claim 2, with the property that said trap is stabilized by a steep gradient in the magnetic field-strength surrounding the bubble as powered by said pluralities of current loops.

4. A method for trapping bubbles of conductive matter according to claim 1, with the property that said alternating states have, respectively, the closed topology of a torus and the open topology of a multipole magnetic field.

5. A method for trapping bubbles of conductive matter according to claim 1, with the property that said matter assumes alternatingly the topology of a hollow torus and a poloidal partition thereof into a plurality of small tori, corresponding respectively to the two said toroidal and poloidal states of the magnetic field.

6. A method for trapping bubbles of conductive matter according to claim 1, with the property that said matter consists of a granular material.

7. A method for trapping bubbles of conductive matter according to claim 3, with the property that said matter is a plasma, wherein inductive heating is balanced by radiative output in bremsstrahlung and synchrotron radiation.

8. A method for trapping bubbles of conductive matter according to claim 3, with the property that said matter is an exothermal plasma, wherein the sum of exothermal and inductive heating is balanced by radiative output in bremsstrahlung and synchrotron radiation.

9. A method for trapping bubbles of exothermal plasmas according to claim 8, with the property that the net energy output in radiation and neutral particles is used to drive an external generator.

10. A method for trapping bubbles of exothermal plasmas according to claim 9, with the property that said external generator is a heat engine.
